(19) United States
(12) Patent Application Publication
(10) Pub. No.: US 2010/0116654 A1
(43) Pub. Date: May 13, 2010

(54) FILM COATING APPARATUS

(75) Inventor: CHIA-YING WU, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/503,971

(22) Filed: Jul. 16, 2009

(30) Foreign Application Priority Data
Nov. 10, 2008 (CN) 200810305462.9

(51) Int. Cl. C23C 14/34

(52) U.S. Cl. 204/298.26

(57) ABSTRACT

An exemplary film coating holder includes a main body, a holding member, a first target electrode, a second target electrode and a driving module. The main body defines a chamber therein. The holding member receives in the chamber and has a plurality of through holes. The through holes being configured for receiving workpieces to be coated. The first target electrode and the second target electrode disposed on the main body and configured for supporting a first target material and a second target material respectively. The driving member is disposed on the main body and mechanically coupled with the holding member, and configured for driving the holding member to rotate about a horizontally oriented axis, thus the first targeted material and the second targeted material can be respectively deposit on opposite sides of each of the workpieces.

### BACKGROUND

1. Technical Field

The present disclosure relates to a film coating apparatus, and particularly to a spatter film coating apparatus.

2. Discussion of Related Art

Generally, in a film coating process for workpieces (e.g., lenses), the workpieces are placed on a holding member. After a surface of each workpiece is coated, the workpieces needed to be turned over on the holding member so that the opposite surface of the workpieces can be coated. However, the action of rotating the work-pieces needs to be manually implemented, which will break the seal of the processing chamber and is time consuming and inefficient.

Therefore, a new film coating apparatus is desired to overcome the shortcomings described above.

### BRIEF DESCRIPTION OF THE DRAWINGS

Many aspects of the present film coating apparatus can be better understood with reference to the following drawings. The components in the drawings are not necessarily to scale, the emphasis instead being placed upon clearly illustrating the principles of the present film coating apparatus. Moreover, in the drawings, like reference numerals designate corresponding parts throughout the several views.

FIG. 1 is a schematic view of a film coating apparatus in accordance with an exemplary embodiment.

FIG. 2 is a cutaway view of the film coating apparatus of FIG. 1.

### DETAILED DESCRIPTION

Reference will now be made to the drawings to describe in detail exemplary embodiments of the film coating apparatus.

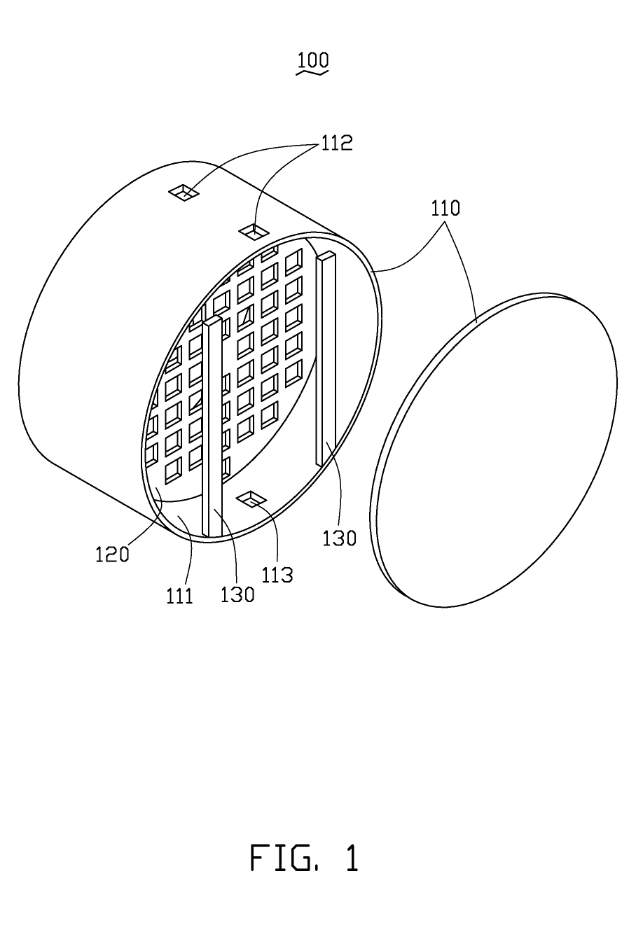

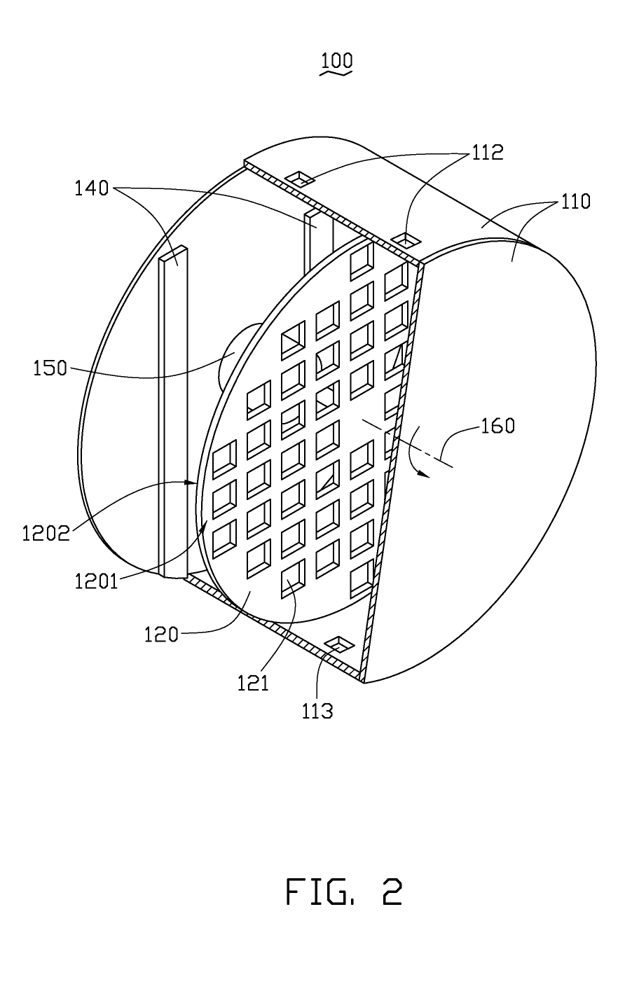

Referring to FIGS. 1 and 2, a film coating apparatus 100, in accordance with an exemplary embodiment, includes a main body 110, a holding member 120, two first target electrodes 130, two second target electrodes 140, and an driving member 150.

The main body 110 is columnar-shaped. The main body 110 defines a chamber 111 therein. The main body 110 includes inlet openings 112 and outlet openings 113 communicated with the chamber 111. The outlet openings 113 are configured for venting air from the chamber 111 for creating an initial vacuum in the chamber 111. A discharge gas, such as argon or nitrogen, can be filled into the chamber 111 through the inlet openings 112.

In the present embodiment, the holding member 120 is received in the center of the chamber 111 to separate the chamber 111 into two equal sections. The holding member 120 is generally disc-shaped and has a central axis 160. The holding member 120 includes a first surface 1201 and a second surface 1202 opposite to the first surface 1201. A plurality of through holes 121 is defined through the first surface 1201 and the second surface 1202 parallel to the central axis 160. The shape of the through holes 121 may be rectangular, fan-shaped, circular, etc. In the present embodiment, the shape of the through holes 121 is rectangular. The through holes 121 have the same size and are arranged symmetrically about the central axis 160, on the main body 110. The through holes 121 are respectively configured for receiving workpieces to be coated. The holding member 120 is made of electrically conductive material, such as copper, aluminum, or iron, so it can be used as target electrode in the process of coating.

In the present embodiment, there are two first target electrodes 130 and two second target electrodes 140. The first target electrodes 130 and the second target electrodes 140 are flat-shaped and independently controlled. The first target electrodes 130 and the second target electrodes 140 are disposed on the main body 110 and located at two opposite sides of the holding member 120. In the present embodiment, the first target electrodes 130 face the first surface 1201 of the holding member 120, and the second target electrodes 140 are face the second surface 1202 of the holding member 120. The first electrodes 130 and the second electrodes 140 are configured for supporting a first target material and a second target material respectively. Therefore, the first target material and the second target material can be deposited on opposite sides of each of the workpieces. It can be understood that the first target electrodes 130 and the second target electrodes 140 may be controlled at the same time.

The driving member 150 is disposed on the main body 110 and mechanically coupled to the holding member 120. The driving member 150 is configured for driving the holding member 120 to rotate around the central axis 160. The driving member 150 is selected from the group consisting of a rotary motor, a rotary cylinder etc.

In operation, air is vented from the chamber 111 through the outlet openings 113 to establish an initial vacuum in the chamber 111, then filling discharge gas into the chamber 111 through the inlet openings 112. Drawing on an external power source, the first target electrodes 130 and the second target electrodes 140 are charged thus ionizing the discharge gas. The ions strike the first target material and the second target material thereby imparting energy from the ion to the first target material and the second target material, thus the first target material and the second target material are atomized to form a film on the two surfaces of the workpieces respectively. In the process of coating, because the driving member 150 drives the holding member 120 to rotate, the first target material and the second target material can evenly and respectively be coated on the two surfaces of the workpieces.

It can be understood that the film coating apparatus 100 can comprise more than two first target electrodes and more than two second target electrodes. Also, different types of target materials on different target electrodes are easily supported.

Comparing to the related art, the film coating apparatus 100 can evenly coat two surfaces of workpieces at the same time. Furthermore, the film coating apparatus 100 can coat different materials onto the two surfaces of the workpieces at the same time. Therefore, the film coating apparatus 100 is more efficient and can save much time in the film coating process.

It is to be understood, however, that even though numerous characteristics and advantages have been set forth in the foregoing description of embodiments, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A film coating apparatus, comprising:
a main body defining a chamber therein;
a holding member received in the chamber and partitioning the chamber into a first section and a second section, the holding member having a plurality of through holes each in communication with the first and second sections, the through holes being configured for receiving workpieces to be coated;
a first target electrode and a second target electrode disposed on the main body and respectively located at opposite sides of the holding member, the first target electrode and the second target electrode being configured for supporting a first target material and a second target material respectively;
a driving member disposed on the main body and mechanically coupled with the holding member, the driving member configured for driving the holding member to rotate about a horizontally oriented axis, thus the first targeted material and the second targeted material being respectively deposited on opposite sides of each of the workpieces.

2. The film coating apparatus of claim 1, wherein the holding member is disc-shaped.

3. The film coating apparatus of claim 1, wherein the holding member is made of metal.

4. The film coating apparatus of claim 1, wherein the driving member is selected from the group consisting of a rotary motor, and a rotary cylinder.

5. The film coating apparatus of claim 1, wherein the first target electrode and the second target electrode are flat.

6. The film coating apparatus of claim 1, wherein the size of the first section of the chamber is equal to that of the second section of the chamber.

7. The film coating apparatus of claim 1, wherein the through holes are arranged in an array.

8. The film coating apparatus of claim 1, wherein the holding member comprises a first surface and a second surface opposite to the first surface, the through holes are defined through the first surface and the second surface, the first target electrode is opposite to the first surface and the second target electrode is opposite to the second surface.

9. The film coating apparatus of claim 1, wherein the chamber of the main body further comprises an inlet opening and an outlet opening communicating with the chamber.
